(19) United States
(12) Patent Application Publication
(10) Pub. No.: US 2023/0279552 A1
(43) Pub. Date: Sep. 7, 2023

(54) PROCESSING SYSTEM FOR SEMICONDUCTOR WAFERS

(71) Applicant: ASM IP Holding, B.V., Almere (NL)

(72) Inventor: Viljami Pore, Helsinki (FI)

(21) Appl. No.: 18/172,158

(22) Filed: Feb. 21, 2023

Related U.S. Application Data
(60) Provisional application No. 63/315,922, filed on Mar. 2, 2022.

(51) Int. Cl. C23C 16/54; C23C 16/02; C23C 16/56; C23C 16/455

(52) U.S. Cl. CPC C23C 16/54; C23C 16/02; C23C 16/56; C23C 16/45544; H01L 21/02271

(57) ABSTRACT

The present disclosure pertains to embodiments of a semiconductor processing system and method for treating a semiconductor wafer. The processing system comprises a reactor, a wafer handling assembly, and treatment unit disposed vertically adjacent to the wafer handling assembly. The system and method minimize a total floor space occupied by the system without sacrificing the processing capacity.

### BACKGROUND OF THE DISCLOSED TECHNOLOGY

### Field

The field generally relates to a semiconductor processing device, and more particularly to a system and method for processing a semiconductor wafer.

### Background

A semiconductor processing typically utilizes a large area of production floor space within a clean room environment. In the production floor space, various semiconductor processing devices are arranged and the floor space can be scarce and costly. During semiconductor processing, a reactant vapor is fed into a process chamber to deposit a film on a wafer. Various types of pre- or post-deposition treatments can be applied in the process to improve film deposition properties. The treatment can be pre-deposition, post-deposition or cyclic (e.g., deposition-treatment-deposition-treatment). It is important to perform the deposition and other treatment processes using a small footprint. Accordingly, there remains a continuing need for improved semiconductor processing devices.

### SUMMARY

In view of the above mentioned situation, one object of one or more aspects of the disclosed embodiments is to provide a semiconductor processing system for treating a wafer, in which the treatment unit is arranged where there is free space.

In one embodiment, a semiconductor processing system for treating a wafer may comprise a reactor configured to deposit a film on the wafer and a treatment unit for treating the film on the wafer. The system may further comprise a wafer handling robot configured to transfer the wafer to the reactor, for example in a vacuum state, and a wafer handling assembly may be configured to accommodate or interact with the wafer handling robot such that the robot arm may pick up and unload the wafer in the wafer handling assembly. The treatment unit may be disposed vertically over the wafer handling assembly. The wafer handling assembly may comprise a chamber in which the wafer is held by the wafer handling robot. The wafer handling robot may comprise an arm, a support or other structure that transfers the wafer. The wafer handling assembly may be a transfer module (TM), a loadlock module (LL), or an atmospheric module (ATM). The treatment unit may comprise a first process window on a side facing the wafer handling assembly while the wafer handling assembly comprises a second process window on a side facing the treatment unit. The first process window are aligned with the second process window, when the wafer handling assembly is disposed vertically over the transfer unit.

In another embodiment, a semiconductor processing system for treating a wafer may comprise a plurality of the reactors, a plurality of the wafer handling assemblies, and at least one of the wafer handling robot. One of the plurality of the wafer handling assemblies may be the transfer module (TM) comprising the wafter handling robot configured to transfer the wafer to a reactor of the plurality of the reactors for a treatment process. At least one of the plurality of the wafer handling assemblies may be the loadlock module (LL) configured to receive the wafer from ambient air pressure state and the wafer handling robot of the transfer module (TM) transfers the wafer in the loadlock module to the reactor in a vacuum state. At least one of the treatment unit is disposed vertically over at least one of the transfer module (TM) and the loadlock module (LL). The system may further comprise at least another one of the plurality of the wafer handling assemblies which can be an atmospheric transfer module (ATM) comprising the wafer handling robot configured to transfer the wafer to the loadlock module (LL). The treatment unit may be disposed vertically over the atmospheric transfer (ATM) or inside the atmospheric transfer (ATM). The plurality of reactors are arranged around the one of the plurality of wafer handling assemblies.

In yet another embodiment, a semiconductor processing system for treating a wafer may comprise a plurality of reactors, a plurality of treatment units for treating the film on the wafer. At least one of the plurality of treatment units is configured to deposit a film on a wafer or is configured for other processing such as etching. The system may further comprise a first wafer handling assembly comprising the wafer handling robot configured to transfer the wafer to a reactor of the plurality of reactors for a deposition process and a second wafer handling assembly, configured to hold the wafer and a third wafer handling assembly comprising the wafer handling robot configured to receive a wafer from ambient air and to transfer the wafer to the second wafer handling assembly. The plurality of treatment units are disposed vertically adjacent to at least one of the first wafer handling assembly and the second wafer handling assembly. The plurality of reactors may be arranged around the first wafer handling assemblies.

Another object of one or more aspects of the disclosed embodiments is to provide a method for treating a semiconductor wafer by a semiconductor processing system which comprises a reactor configured to deposit a film on a wafer, a treatment unit for treating a film and a wafer handling assembly configured to transfer the wafer to the reactor, the treatment unit being disposed vertically adjacent to the wafer handling assembly.

In one embodiment, the method may comprise providing the wafer to the wafer handling assembly, transferring the wafer to the reactor through the wafer handling assembly, and depositing a reactant vapor onto the wafer. The method may further comprise transferring the wafer to the wafer handling assembly and holding the wafer underneath treatment unit and conducting thermal annealing. The deposition steps and annealing step may be repeated.

### BRIEF DESCRIPTION OF THE DRAWINGS

The foregoing and other objectives and advantages will appear from the description to follow. In the description reference is made to the accompanying drawing, which forms a part hereof, and in which is shown by way of illustration specific embodiments in which the disclosed embodiments may be practiced. These embodiments will be described in sufficient detail to enable those skilled in the art to practice the disclosed embodiments, and it is to be understood that other embodiment may be utilized and the structural changes may be made without departing from the scope of the disclosed embodiments. The accompanying drawing, therefore, is submitted merely as showing the preferred exemplification of the disclosed embodiments. Accordingly, the following detail description is not to be taken in a limiting sense, and the scope of the present disclosed embodiments is best defined by the appended claims.

FIG. 1 is a schematic diagram of a conventional semiconductor processing device.

FIG. 2a shows a schematic top view of a semiconductor processing device having eight reactors without a separate treatment unit.

FIG. 2b shows a schematic side view of the semiconductor processing device of FIG. 2a.

FIG. 3a shows a schematic top view of a semiconductor processing device in accordance with one embodiment of the present disclosed technology, in which a treatment unit is disposed over a wafer handling assembly comprising a transfer module (TM) configured to transfer the wafer to the reactor in a vacuum state.

FIG. 3b shows a schematic top view of a semiconductor processing device in accordance with another embodiment of the present disclosed technology, in which a treatment unit configured to treat a plurality of wafers at a time is disposed over a wafer handling assembly comprising a transfer module (TM).

FIG. 3c show a schematic top view of a semiconductor processing device in accordance with another embodiment of the present disclosed technology, in which a plurality (e.g., four) of the treatment units are disposed over a wafer handling assembly comprising a transfer module (TM).

FIG. 4a shows a schematic top view of a semiconductor processing device in accordance with another embodiment of the present disclosed technology, in which the treatment unit is disposed over a wafer handling assembly comprising a loadlock module (LL).

FIG. 4b shows a schematic top view of a semiconductor processing device in accordance with another embodiment of the present disclosed technology, in which a first treatment unit is disposed over a transfer module and a second treatment unit is disposed over a loadlock module.

FIG. 4c shows a schematic top view of a semiconductor processing device in accordance with another embodiment of the present disclosed technology, in which a plurality of treatment units are disposed over a transfer module and a treatment unit is disposed over each loadlock module. A plurality of the treatment units are disposed on the wafer handling, assembly configured to transfer the wafer to the reactor in a vacuum state.

FIG. 5a shows a schematic side sectional view of the semiconductor processing device of FIG. 3a.

FIG. 5b is a schematic illustration of a wafer handling robot.

FIG. 6a shows a schematic side sectional view of the semiconductor processing device of FIG. 4a.

FIG. 6b is a schematic illustration of a substrate support station.

FIG. 6c shows a schematic side sectional view of the semiconductor processing device of FIG. 4b.

FIG. 6d shows a schematic side sectional view of the semiconductor processing device in accordance with another embodiment of the present disclosed technology, in which the treatment unit is disposed vertically over or inside of an atmospheric transfer module (ATM).

FIG. 7a shows a schematic top view of a semiconductor processing device in accordance with another embodiment of the present disclosed technology in which the treatment unit is disposed on the wafer handling assembly configured to transfer the wafer to the one of the plurality of wafer handling assemblies.

FIG. 7b shows a schematic top view of a semiconductor processing device in accordance with another embodiment of the present disclosed technology, in which the treatment unit is disposed on the wafer handling assembly configured to transfer the wafer to the one of the plurality of wafer handling assemblies.

FIG. 8 is a flow chart illustrating a semiconductor processing method according to various embodiments.

### DETAILED DESCRIPTION

Hereafter, an apparatus and a method of the present disclosed technology will be described in detail by way of various embodiments shown in the attached drawings. Unless defined otherwise, all technical and scientific terms used herein have the same meaning as is commonly understood by one skill in the art.

In order to minimize a floor space occupied by a processing system, radiation sources for the treatment positioned next to a deposition chamber have been proposed in the past. However, this configuration has the practical problem that a process window will become impermeable to radiation, as the deposited material accumulates also on the window.

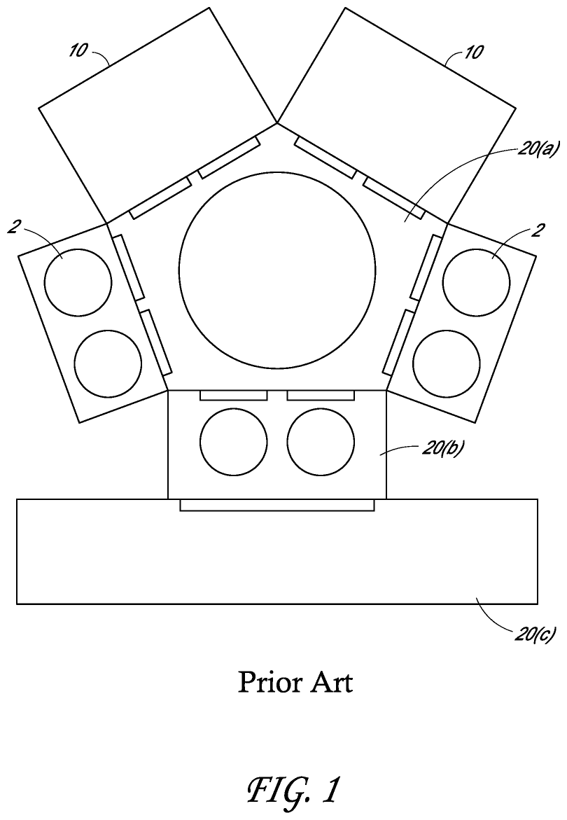

As indicated in FIG. 1, system can include a plurality of reactors 2 and a plurality of treatment modules 10 disposed around a transfer module 20(a). The treatment modules 10 can be configured to treat the wafers to improve the deposition of the film on the wafer. In the illustrated embodiment, the treatment modules 10 can treat the film on the wafer after deposition. In other embodiments, the treatment modules 10 may additionally or alternatively be configured to treat the wafer before deposition. The transfer module 20(a) takes a wafer from the loadlock module 20(b) and convey the wafer to the reactors 2 disposed around the transfer module 20(a) so as to deposit a film on the wafer. The wafer having the film deposited thereon can then be conveyed to the treatment units 10 by the transfer module 20(a). As the treatment unit 10 are also disposed around the transfer module 20(a), as more treatment units 10 are added, the total floor space occupied by a horizontally integrated system increases which reduces processing capacity and yield. Accordingly, there is a need in the art to have a semiconductor processing system which occupies reduced or minimal floor space as compared to conventional systems.

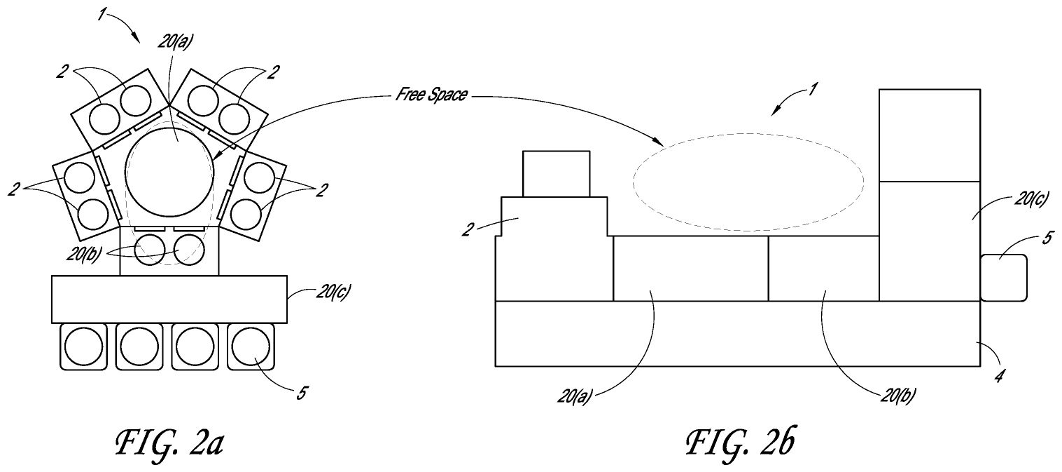

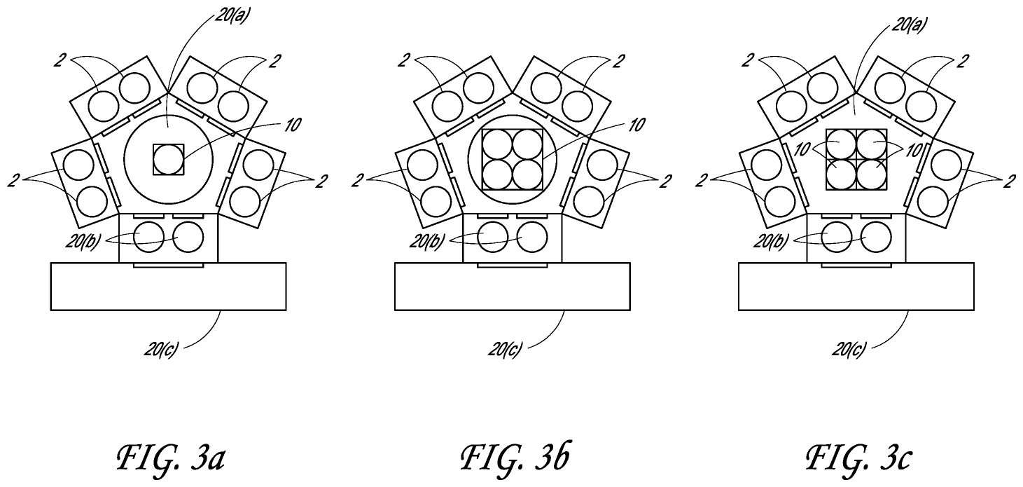

FIG. 2a and FIG. 2b show a typical semiconductor processing system with a plurality of (e.g., eight) reactors and wafer handling assemblies 20, including, e.g., a transfer module (TM) 20(a), a loadlock module 20(b), and an atmospheric (ATM) module 20(c), as described herein. With the disclosed system, the atmospheric transfer module (ATM) 20(c) comprising a wafer handling robot (23) (see FIG. 5b), which takes wafer W from wafer storages 5 and loads the wafers W into loadlock module (LL) 20(b) while exposed to ambient air or the cleanroom atmosphere. The wafer handling robot (23) of the transfer module (TM) 20(a) takes the wafer W from the loadlock module (LL) 20(b) in a vacuum state while exposed to a vacuum (or, in other embodiments, exposed to ambient air) and conveys the wafer W to the reactor 2 to deposit a film on the wafer W. In various embodiments disclosed herein (see FIGS. 3a et seq.), the wafer W is conveyed to at least one wafer handling assembly 20 disposed underneath a treatment unit 10 for treating the film on the wafer W. During the processing, the wafer W can be held in the loadlock module (LL) 20(b) or transfer module (TM) 20(a) while other wafers are being processed int the reactor 2. Without reducing the processing capacity and increasing the total floor space occupied by the system, a free space indicated in the figures is utilized in the disclosed embodiments. As disclosed herein, the treatment units 10 can be provided in the free space over the wafer handling assemblies in order to reduce a lateral footprint of the treatment units 10.

FIG. 3a illustrates a semiconductor processing system 1 for treating a wafer W (not shown in the figure), which may comprise a reactor 2 configured to deposit a film on the wafer W and a treatment unit 10 for treating the film on the wafer W. The reactor 2 can be used for any suitable type of deposition process, such as Chemical Vapor Deposition (CVD) or Atomic Layer Deposition (ALD). The system 1 may further comprise a transfer module 20(a) comprising the wafer handling robot (23) configured to transfer the wafer W to the reactor 2 in a vacuum state. The treatment unit 10 may be disposed vertically adjacent to (e.g., disposed vertically over) the transfer module 20(a). As shown in FIG. 5a, the treatment unit 10 may comprise a first process window 11 on a side facing the wafer handling assembly (bottom panel 12 thereof) while the wafer handling assembly 20(a) comprises a second process window 21 on a side facing the treatment unit (top panel 22 thereof). The first process window 11 can be aligned with the second process window 21, when the treatment unit 10 is disposed vertically over the wafer handling assembly 20. The system 1 may be arranged on a utility enclosure 4, in which electronics, gas and pumps lines are disposed. The system 1 may further comprise a wafer storage module 5, which can comprise one or multiple wafer boats configured to store wafers before or after processing.

The treatment unit 10 may comprise a radiation source 13 configured to emit electromagnetic waves (e.g., ultraviolet (UV) radiation, infrared (IR) radiation, or any other suitable type of radiation) toward the first process window 11 to treat the film on the wafer W. The transfer module 20(a) may comprise a wafer handling robot 23 configured to hold the wafer W being processed underneath the second process window 21. See FIG. 5b. The second process window 21 can be covered with or formed of an optically transparent material 24 for allowing the electromagnetic waves to pass therethrough. The radiation permeable material 24 may comprise fused silica in various embodiments.

The semiconductor processing system 1 may comprise a plurality of the reactors 2, and the wafer handling assembly can comprise a plurality of wafer handling modules, including, e.g., a transfer module 20(a), a loadlock module 20(b), and an atmospheric (ATM) module 20(c), as described herein. The transfer module 20(a) may comprise the wafer handling robot (23) configured to transfer the wafer W to a reactor 2 of the plurality of the reactors for a treatment process in vacuum state. The loadlock module 20(b) may be configured to receive the wafer W from ambient air pressure state and the wafer handling robot (23) of the transfer module (TM) 20(a) transfers the wafer W to the reactor 2.

A treatment unit 10 can be disposed over any or all of the wafer handling assemblies 20 disclosed herein. For example, a treatment unit 10 ca be disposed over at least one of the transfer module 20(a), the loadlock module 20(b) and the atmospheric module 20(c). The number of the treatment units 10 and which of the wafer handling assemblies 20 to be equipped with the treatment units 10 may be determined based on process time for a film deposition and a post deposition treatment. As described herein, the present disclosed technology provides not only the system which occupies minimal or a reduced amount of floor space as compared conventional systems, but also a modular process system which can improve process capacity and reduce idling time of each component within the system 1.

As shown in FIG. 5b, the first process window 11 of the treatment unit 10 can be disposed vertically over the one of the plurality of the wafer handling assemblies 20(a). The first process window 11 may be configured to cover a plurality of wafers at a time, while the second process window 21 of the one of the plurality of the wafer handling assemblies 20(a) may be configured to cover a plurality of wafers at a time as well. See FIG. 3b. Thus, the treatment unit 10 disposed vertically over the one of the plurality of the wafer handling assemblies 20(a) can treat a plurality of wafers at a time.

FIG. 3c shows an embodiment, in which the one of the plurality of the wafer handling assemblies (e.g., the transfer module 20(a) comprises a plurality of the second process windows 21 on the top panel 22. A corresponding treatment unit 10 can be disposed vertically over each of the plurality of second process windows 21. Each of the treatment units 10 may be have different radiation sources 13, which may emit the same or a different type of radiation from one another. Although FIGS. 3b and 3c indicate the configuration for treating four wafers W at a time, any suitable number of wafers W can be treated.

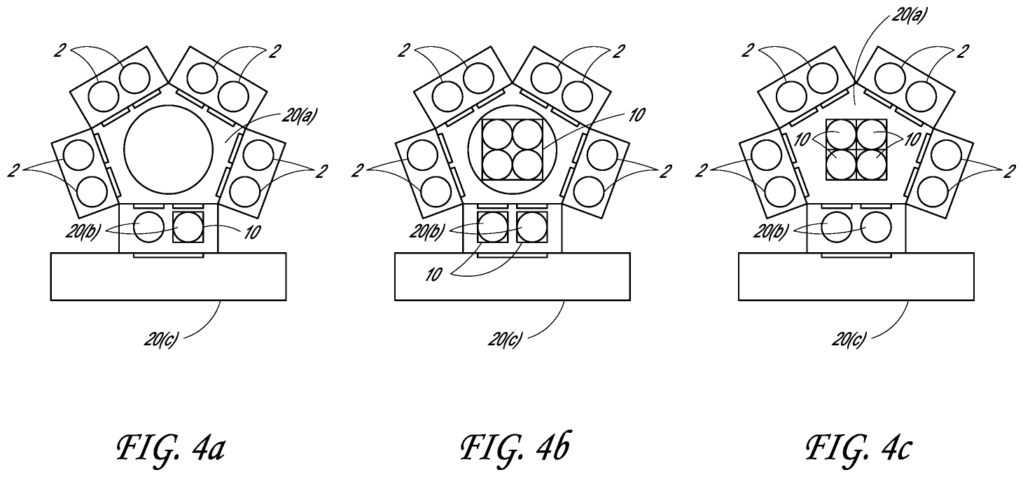

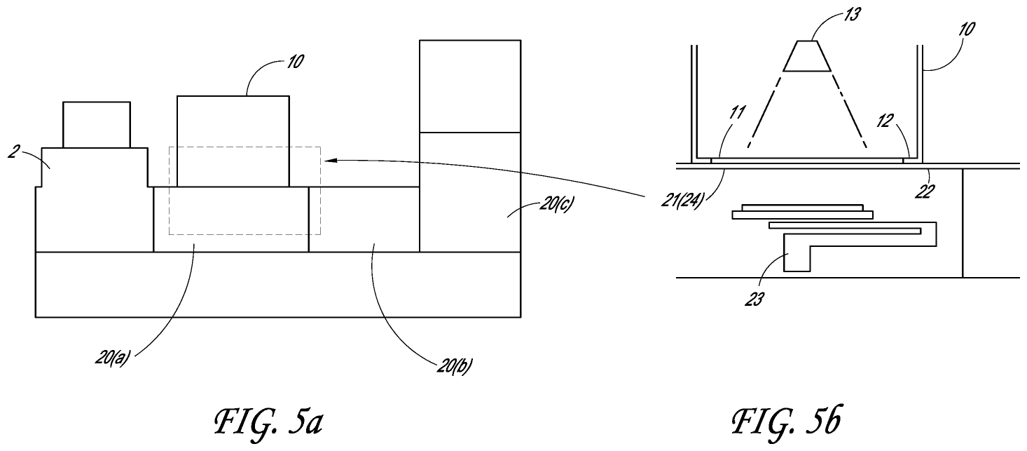

Turning to the embodiment of FIG. 4a, the treatment unit 10 may be disposed vertically adjacent to (e.g., disposed over) at least one of the plurality of the loadlock module 20(b). As shown in FIG. 4b, the first treatment unit 10 can be disposed over the transfer module 20(a) and a second treatment unit can be disposed over each loadlock module 20(b). The first treatment unit 10 may be configured to treat a plurality of (e.g., four) wafers W at a time and the second treatment unit can comprise a plurality of treatment units 10, each of which is configured to treat a single wafer at a time. The transfer module 20(a) may comprises a plurality of the second process windows 21 on the top panel 22, and a treatment unit 10 may be disposed vertically over each of the second process windows 21. FIG. 4c shows an embodiment in which a plurality of (e.g., four) treatment units 10 are disposed over four corresponding regions of the transfer module 20(a) to separately treat the wafers. A plurality of treatment units 10 can be disposed over two regions of the loadlock module 20(b). Each of treatment units 10 disposed over the transfer module 20(a) and loadlock module 20(b) may have different radiation sources 13 so as to separately treat the plurality of wafers W. In other embodiments, a common radiation source can be used over the transfer module 20(a) or the loadlock module 20(b) so as to treat multiple wafers at a time.

FIG. 5a shows a schematic side view of the semiconductor processing system 1 of FIG. 3a having the treatment unit 10 over the transfer module 20(a). As indicated in FIG. 5b, the first process window 11 of the treatment unit 10 can be aligned with the second process window 21 of the transfer module 20(a). The transfer module 20(a) may comprise a wafer handling robot 23 configured to hold the wafer W underneath the second process window 21 during a treatment process. Although the treatment unit 10 is disposed vertically over the transfer module 20(a), the wafer handling robot 23 need not provide any vertical movement (Y direction in FIG. 5b) to convey the wafer W to the treatment unit 10, but may instead move the wafers W generally horizontally (X direction in FIG. 5b) through the system 1. The second process window 21 may be covered with or formed of an optically transparent material 24 for allowing the electromagnetic waves emitted from the radiation source 13 within the treatment unit 10 to pass therethrough. The radiation permeable material 24 may comprise fused silica in various embodiments. FIG. 5a also shows a utility enclosure 4, in which electronics, gas and pumps lines are disposed, and an electronic junction box 8,

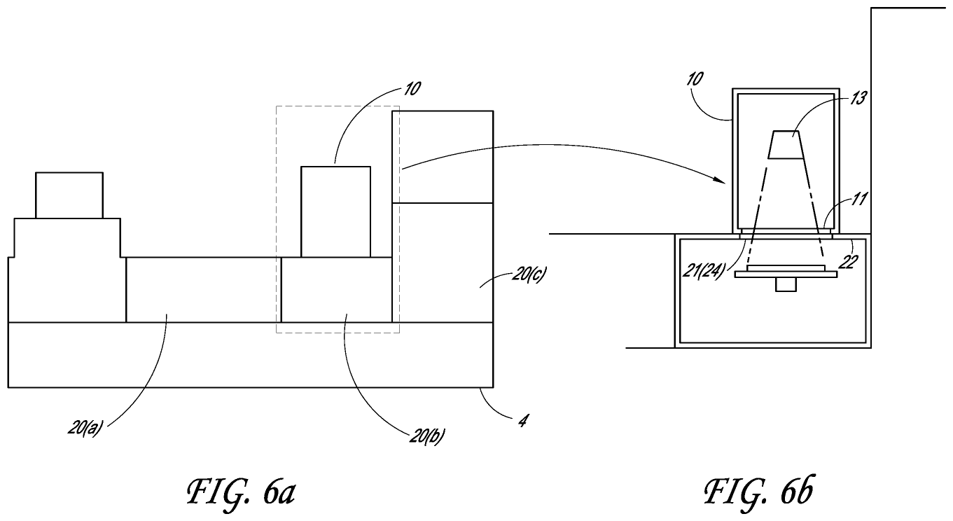

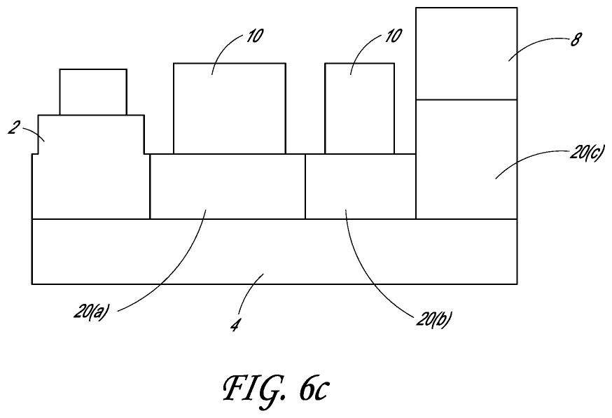

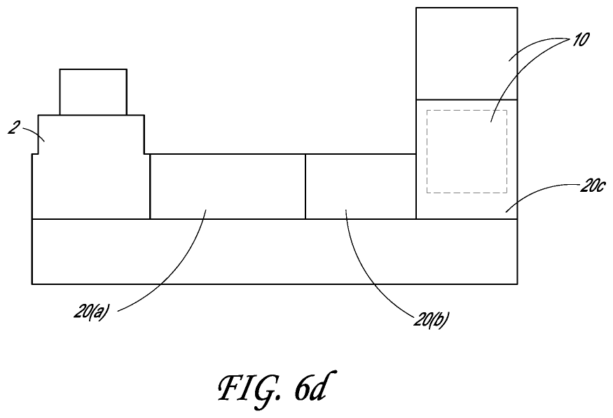

FIG. 6a shows a schematic side view of the semiconductor processing device of FIG. 4a in which the treatment unit 10 is disposed vertically over the loadlock module 20(b). As shown in FIG. 6b, the first process window 11 of the treatment unit 10 can be disposed vertically over and adjacent the second process window 21 of the loadlock 20(b). The loadlock module 20(b) may comprise a substrate support station 33, which is configured to hold the wafer W in process underneath the second process window 21. The wafer handling robot 23 in the transfer module 20(a) may pick up the wafer W on the substrate support station 33 to transfer the wafer W to the reactor 2.

FIG. 6c shows a schematic side sectional view of the semiconductor processing device of FIG. 4b, in which the treatment unit 10 is disposed over the transfer module 20(a) and the loadlock module 20(b).

FIG. 6d shows schematic side sectional view of the semiconductor processing device in accordance with another embodiment, in which the electronic junction box 8 on atmospheric transfer module (ATM) 20(c) is replaced with the treatment unit 10 disposed over an atmospheric transfer module (ATM) 20(c). The electronic junction box 8 can be disposed in another location of the system. Alternately, the treatment unit may be disposed inside of the atmospheric transfer module (ATM) 20(c) and as noted above, the treatment unit 10 can perform a treatment on the wafer W in the ATM module 20(c).

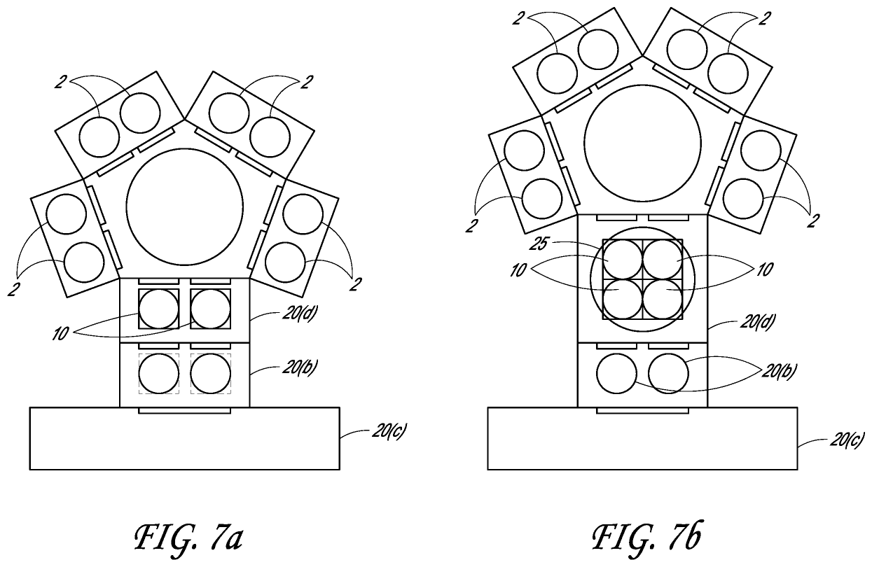

In the embodiment of FIG. 7a, the semiconductor processing device 1 may comprise a plurality of reactors 2, at least one of which is configured to deposit a film on a wafer W, a plurality of treatment units 10 for treating the film on the substrate W, and a plurality of wafer handling assemblies 20. The transfer module 20(a) may comprise the wafer handling robot (23) configured to transfer the wafer W to a reactor of the plurality of reactors 2 for a treatment process. Intermediate transfer module 20(d) may comprise wafer handling robot configured to transfer the wafer W to the transfer module 20(a). At least one of the loadlock module 20(b) are configured receive the wafer W from ambient air pressure state The wafer handling robot 23 of the intermediate transfer module (20d) configured to take the wafer W from the loadlock module 20(b) and transfer the wafer W to the transfer module 20(a) in vacuum state. The wafer handling robot 23 may be further configured to hold the wafer W in process underneath a process window of the intermediate transfer module (20d). The plurality of treatment units 10 may be disposed vertically over the intermediate transfer module 20(d) or to another intermediate transfer module 20(d) and the loadlock module 20(b). The plurality of reactors 2 may be arranged around the transfer module 20(a). As shown in FIG. 1b, the plurality of treatment units 10 may be disposed vertically over the intermediate transfer module 20(d) and the wafer handling robot 23 therein may further comprise a rotating table 25 configured to hold the plurality of wafers W. Each of treatment units 10 may be capable to have a different radiation source 13 from each other. Although FIG. 7b indicates the configuration for treating four wafers W at a time, the present disclosed technology is not limited to this embodiment and may be variously altered or changed as long as it does not depart from the gist of the present disclosed technology.

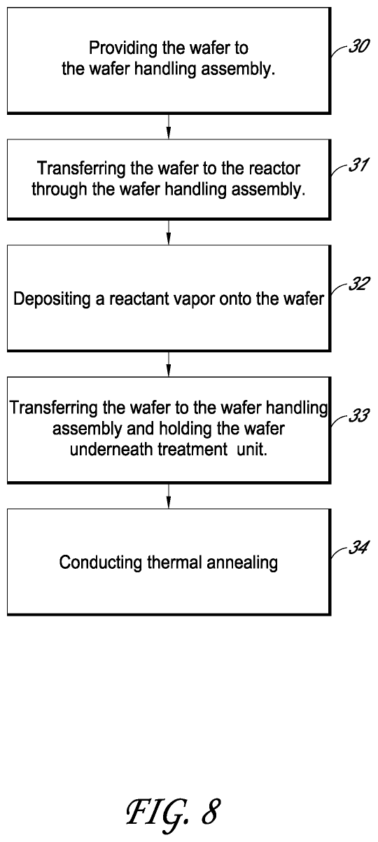

FIG. 8 is a flow chart generally illustrating a method for treating a semiconductor wafer W by the semiconductor processing system according to various embodiments. At block 30, a wafer W is provided to the wafer handling assembly 20. The wafer may be provided from another wafer handling assembly. At block 31, the wafer handling assembly 20 can transfer the wafer W to the reactor 2. At block 32, a reactant vapor can be deposited on the wafer W to form a film thereon. At block 33, the wafer W can be transferred to the wafer handling assembly 20 and held underneath the treatment unit 10. At block 34, a treatment process (e.g., a thermal annealing process) can be conducted by emitting electromagnetic waves from the radiation source 13 to the wafer W in order to improve filth property. In some embodiments, the deposition process and the treatment processes may be cyclically repeated. The order of the method in the flow chart needs not to be the same as that illustrated in FIG. 8. The treatment unit can treat the wafer before or after the film deposition in various embodiments.

In each of the illustrated embodiments, the treatment unit(s) 10 are shown as being disposed vertically adjacent and over the wafer handling assembly 20. In other embodiments, however, the treatment unit(s) 10 may be disposed vertically adjacent and underneath the wafer handling assembly 20. For example, in some embodiments, the wafer W may be supported by a ring-shaped support with the bottom of the wafer W exposed to the treatment unit 10 underneath the wafer.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted fairly based on the language employed in the claims and not limited to the examples described in the present specification or during the prosecution of the application, which examples are to be construed as non-exclusive.

What is claimed is:

1. A semiconductor processing system for treating a wafer, the system comprising:
a reactor configured to deposit a film on the wafer,
a treatment unit for treating the wafer before or after deposition of the film, a wafer handling robot configured to transfer the wafer, and
a wafer handling assembly configured to accommodate or interact with the wafer handling robot,
wherein the treatment unit is disposed vertically over the wafer handling assembly.

2. The semiconductor processing system according to claim 1, wherein:
the treatment unit comprises a first process window on a side facing the wafer handling assembly,
the wafer handling assembly comprises a second process window on a side facing the treatment unit; and
the treatment unit is disposed vertically over the wafer handling assembly aligning the first process window with the second process window.

3. The semiconductor processing system according to claim 2, wherein:
the treatment unit comprises a radiation source configured to emit electromagnetic waves, and
the wafer handling assembly comprises a substrate handling system configured to hold the wafer in process underneath the second process window.

4. The semiconductor processing system according to claim 3, wherein the second process window is covered with or formed of an optically transparent material for allowing the electromagnetic waves to pass therethrough.

5. The semiconductor processing system according to claim 4, wherein the radiation permeable material comprises fused silica.

6. The semiconductor processing system according to claim 1, wherein the reactor comprises a Chemical Vapor Deposition (CND) device or Atomic Layer Deposition (ALD) device.

7. The semiconductor processing system according to claim 1, wherein:
the semiconductor processing system comprises a plurality of the reactors, a plurality of the wafer handling assemblies, and at least one of the wafer handling robot,
the wafer handling assembly comprises at least one of a transfer module (TM), a loadiock module (LL), and an atmospheric module (ATM),
the TM comprises the wafer handling robot configured to transfer the wafer from the LL to a reactor of the plurality of the reactors for a treatment process,
and
at least one of the treatment units is disposed over at least one of the TM and LL.

8. The semiconductor processing system according to claim 7, wherein the wafer handling assembly comprises the TM and the and
wherein a corresponding treatment unit is disposed over the TM and the LL.

9. The semiconductor processing system according to claim 8,
wherein the TM is under vacuum.

10. The semiconductor processing system according to claim 9 wherein the wafer handling assembly further comprises the ATM,
wherein the ATM comprises the wafer handling robot,
wherein the LL is disposed between TM and the ATM.

11. The semiconductor processing system according to claim 10, wherein a corresponding treatment unit is disposed vertically over the wafer handling robot of the ATM, and
wherein the ATM is exposed to atmospheric pressure.

12. The semiconductor processing system according to claim 11, wherein the corresponding treatment unit is disposed vertically over the ATM.

13. The semiconductor processing system according to claim 11, wherein the corresponding treatment unit is disposed inside of the ATM.

14. The semiconductor processing system according to claim 7, wherein the treatment unit is disposed vertically over the TM and configured to treat one wafer at a time.

15. The semiconductor processing system according to claim 7, wherein:
the treatment unit is disposed vertically over the TM and is configured to treat a plurality of wafers at a time.

16. The semiconductor processing system according to claim 7, wherein:
the TM comprises a plurality of the second process windows on the top panel, and
the treatment unit is disposed vertically over each of the plurality of the second process windows.

17. The semiconductor processing system according to claim 15, wherein
the treatment unit disposed over the TM is configured to treat a plurality of wafers at a time.

18. The semiconductor processing system according to claim 9, wherein
the TM comprises a plurality of the second process windows on the top panel, and
the treatment unit is disposed vertically over each of the second process windows.
